(19) United States
(12) Patent Application Publication
(10) Pub. No.: US 2025/0248052 A1
(43) Pub. Date: Jul. 31, 2025

(54) MEMORY DEVICE

(71) Applicant: MACRONIX INTERNATIONAL CO., LTD., Hsinchu (TW)

(72) Inventors: Wei-Chih Chien, New Taipei City (TW); Huai-Yu CHENG, Hsinchu City (TW); Chiao-Wen YEH, New Taipei City (TW); Jeffrey Xuan ZHENG, Flushing, NY (US)

(21) Appl. No.: 18/668,878

(22) Filed: May 20, 2024

Related U.S. Application Data
(60) Provisional application No. 63/626,514, filed on Jan. 29, 2024.

(51) Int. Cl. H10B 99/00

(52) U.S. Cl. CPC H10B 99/10

(57) ABSTRACT

A memory device includes a first electrode, a second electrode and a memory layer disposed between the first electrode and the second electrode. The memory layer includes a composition including X wt % Cu, Y wt % Ge and Z wt % Se. X ranges between 3.33 and 26.66. Y ranges between 28.33 and 86.66. Z ranges between 10 and 45.

This application claims the benefit of U.S. provisional application Ser. No. 63/626,514, filed Jan. 29, 2024, the subject matter of which is incorporated herein by reference.

### BACKGROUND OF THE INVENTION

### Field of the Invention

The invention relates in general to a semiconductor device, and more particularly to a memory device.

### Description of the Related Art

Recently, many switching element applications have been developed in integrated circuits. One type of switching element is called an ovonic threshold switch (OTS). The ovonic threshold switch has a bipolar material, and a turn-on state can be formed when a threshold voltage (Vt) is reached, and the resistance is greatly reduced. When the voltage drops below the threshold voltage, the high resistance is restored, and a turn-off state can be formed. Ovonic threshold switches can be applied to memory devices. For example, a memory device includes memory cells having memory layers and switch layers connected to each other. However, this type of memory device still faces some electrical problems (such as leakage current), making the reliability of the memory device unwell.

### SUMMARY OF THE INVENTION

The present invention relates to a memory device. A memory layer in the memory device includes a composition making the memory layer have functions of the switch element and the memory element, and making the memory device to have a lower leakage current.

According to an embodiment of the present invention, a memory structure is provided. The memory device includes a first electrode, a second electrode and a memory layer disposed between the first electrode and the second electrode. The memory layer includes a composition including X wt % Cu, Y wt % Ge and Z wt % Se. X ranges between 3.33 and 26.66. Y ranges between 28.33 and 86.66. Z ranges between 10 and 45.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 is a side view of a memory device according to an embodiment of the present invention.

FIG. 2A is a square wave diagram of program and read operations on a memory device according to an embodiment of the present invention.

FIG. 2B is a current-voltage diagram of the read operations of FIG. 2A.

FIG. 3A is a square wave diagram of program and read operations on a memory device according to another embodiment of the present invention.

FIG. 3B shows the current-voltage diagram of the read operations of FIG. 3A.

FIG. 4 is a three-dimensional view of a memory device according to another embodiment of the present invention.

FIG. 5A shows a three-dimensional view of a memory device according to a further embodiment of the present invention.

FIG. 5B shows a top view of a memory cell of the memory device in FIG. 5A.

### DETAILED DESCRIPTION OF THE INVENTION

The following are related embodiments, together with the drawings, to describe the memory structure provided by the present invention in detail. However, the present invention is not limited thereto. The descriptions in the embodiments, such as the detailed structure, the operating method, and the material application, etc., are only for the purpose of illustration, and the scope of protection of the present invention is not limited to the mentioned implementation aspects.

At the same time, it should be noted that this disclosure does not show all possible embodiments. One of ordinary skilled in the art can make changes and modifications to the structures and operating methods of the embodiments to meet the needs of practical applications without departing from the spirit and scope of the present disclosure. Therefore, other implementation aspects not proposed in the present disclosure may also be applicable. Furthermore, the drawings are simplified for the purpose of clearly explaining the contents of the embodiments, and the dimension and ratios in the drawings are not drawn according to the actual product scale. Therefore, the description and the drawings are only used to describe the embodiments, rather than to limit the protection scope of the present disclosure. The same or similar reference numerals are used to represent the same or similar elements.

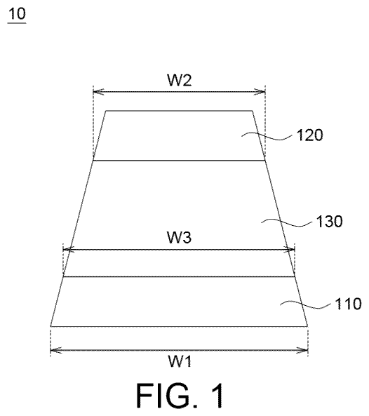

FIG. 1 is a side view of a memory device 10 according to an embodiment of the present invention. Referring to FIG. 1, the memory device 10 includes a first electrode 110, a second electrode 120 and a memory layer 130 disposed between the first electrode 110 and the second electrode 120. The memory layer 130 includes a composition including X wt % Cu (i.e. Copper), Y wt % Ge (i.e. Germanium) and Z wt % Se (i.e. Selenium). X ranges between 3.33 and 26.66. Y ranges between 28.33 and 86.66. Z ranges between 10 and 45. X+Y+Z=100 (around 100, such as 99.99). Moreover, the composition of the memory layer 130 includes GeSe, Ge and Cu₂GeSe₃.

According to an embodiment, the composition of the memory layer 130 includes 10 wt % GeSe, 10 wt % Ge and 80 wt % Cu₂GeSe₃. That is, X=26.66, Y=28.33 and Z=45. The atomic percentage (at %) ratio of the composition of the memory layer 130 including copper, selenium and germanium is 1:4:5 (i.e. Cu:Se:Ge=1:4:5).

According to an embodiment, the composition of the memory layer 130 includes 80 wt % GeSe, 10 wt % Ge and 10 wt % Cu₂GeSe₃. That is, X=3.33, Y=51.66 and Z=45.

According to an embodiment, the composition of the memory layer 130 includes 10 wt % GeSe, 80 wt % Ge and 10 wt % Cu₂GeSe₃. That is, X=3.33, Y=86.66 and Z=10.

According to an embodiment, the composition of the memory layer 130 includes 50 wt % GeSe, 20 wt % Ge and 30 wt % Cu₂GeSe₃.

In the present embodiment, the side view of the memory device 10 may be similar to a trapezoidal structure. For example, a width W1 of a bottom surface of the first electrode 110 is greater than a width W3 of a bottom surface of the memory layer 130; a width W3 of a bottom surface of the memory layer 130 is greater than the width W2 of the bottom surface of the second electrode 120 (i.e., W1>W3>W2). However, the invention is not limited thereto. In other embodiments, the width W1 of the bottom surface of the first electrode 110, the width W3 of the bottom surface of the memory layer 130 and the width W2 of in the bottom surface of the second electrode 120 are the same as each other (i.e., W1=W3=W2).

According to some embodiments, the materials of the first electrode 110 and the second electrode 120 may include a conductive material, and the conductive material is titanium nitride (TIN), carbon (C), tungsten (W), titanium (Ti), nickel (Ni), cobalt (Co), polysilicon or other suitable conductive material. The materials of the first electrode 110 and the second electrode 120 may be the same or different.

In the present embodiment, the memory layer 130 contacts the first electrode 110 and the second electrode 120. That is, there are no other layers between the memory layer 130 and the first electrode 110 and between the memory layer 130 and the second electrode 120. The memory layer 130 does not include phase change memory materials and barrier layers. In other words, the memory device 10 of the present invention does not include phase change memory materials and barrier layers. In some embodiments, the thickness of the memory layer 130 is between 30 nanometers and 40 nanometers, but the invention is not limited thereto. Compared with memory devices including phase change memory materials and/or barrier layers, the memory device 10 of the present invention can have a smaller thickness, which is beneficial to the miniaturization of the memory device. Furthermore, compared to memory devices including phase change memory materials and/or barrier layers, the memory device 10 of the present invention can have better electrical characteristics, such as lower leakage current.

According to some embodiments, the memory device 10 can be performed in the forward and reverse program operations and read operations. For example, when the memory device 10 is performed with a forward program operation (referred to as “F-program”) or a forward read operation (referred to as “F-read”), a forward bias voltage is applied to the second electrode 120, and the first electrode 110 is in a grounded state. When the memory device 10 is performed with a reverse program operation (referred to as “R-program”) or a reverse read operation (referred to as “R-read”), a forward bias voltage can be applied to the first electrode 110, and the second electrode 120 is in a grounded state. In other words, the memory device 10 of the present invention can be performed in a bipolar operation.

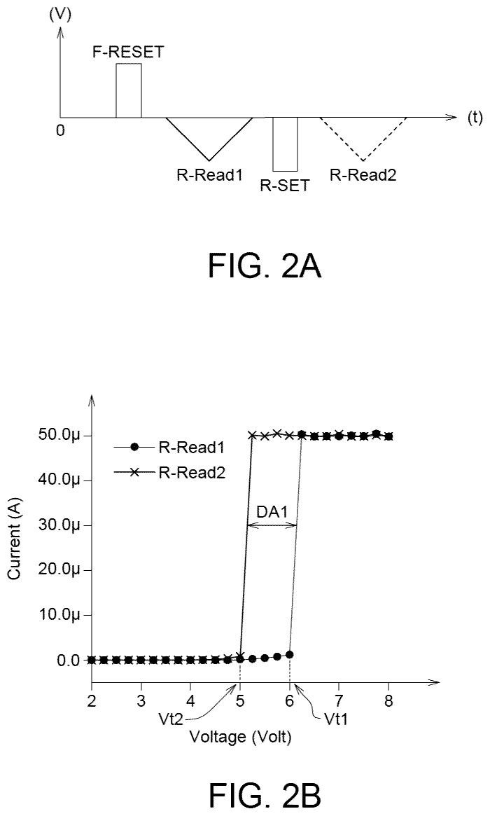

FIG. 2A is a square wave diagram of program and read operations on a memory device (e.g., memory device 10) according to an embodiment of the present invention. The X-axis represents the time and the Y-axis represents the voltage.

Referring to FIG. 2A, a forward reset operation (referred to as “F-RESET”) is firstly performed. After “F-RESET”, a first reverse read operation (referred to as “R-Read1”) is performed. After “R-Read1”, a reverse set operation (referred to as “R-SET”) is performed. After “R-SET”, a second reverse read operation (referred to as “R-Read2”) is performed. Generally speaking, the process from a high-resistance state to a low-resistance state is called “SET”, and the process from a low-resistance state to a high-resistance state is called “RESET”.

FIG. 2B is a current-voltage diagram of the read operations of FIG. 2A. The X-axis represents voltage (V) and the Y-axis represents current (A).

Referring to FIG. 2B, the threshold voltage Vt1 of “R-Read1” is about 6V, the threshold voltage Vt2 of “R-Read2” is about 5V, the memory window DA1 between “R-Read1” and “R-Read2” is shown as a double arrow. It can be seen that two threshold voltages can be read in the reverse read operation, so the “0” and “1” states can be determined. Therefore, the memory layer 130 of the memory device 10 of the present invention is suitable as a memory element. Furthermore, when voltage is less than 5V, the currents of “R-Read1” and “R-Read2” are very small, and the memory device 10 is in a turn-off state. After 5V is applied to the memory device 10, the memory device 10 is in a turn-on state, so the memory layer 130 of the memory device 10 of the present invention is suitable as a switching element.

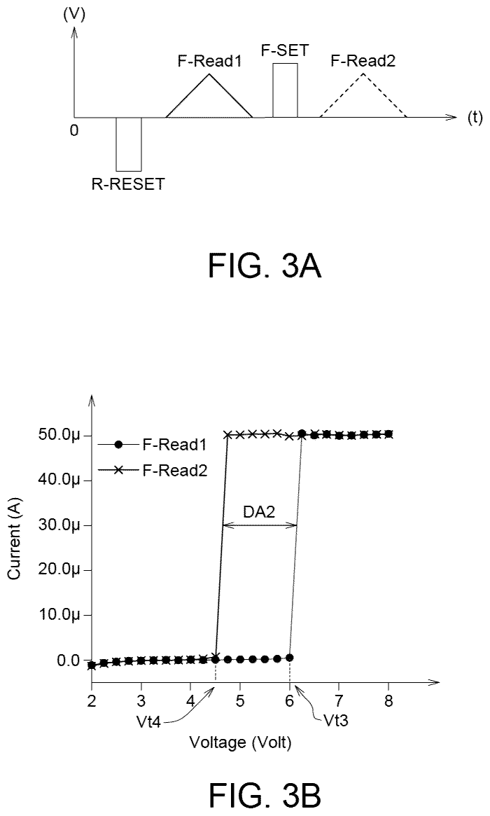

FIG. 3A is a square wave diagram of program and read operations on a memory device (e.g., memory device 10) according to another embodiment of the present invention. The X-axis represents the time and the Y-axis represents the voltage.

Referring to FIG. 3A, a reverse reset operation (referred to as “R-RESET” is firstly performed. After “R-RESET”, a first forward read operation (referred to as “F-Read1”) is performed. After “F-Read1”, a forward set operation (referred to as “R-SET”) is performed. After “F-SET”, a second forward read operation (referred to as “F-Read2”) is performed.

FIG. 3B is a current-voltage diagram of the read operations of FIG. 3A. The X-axis represents voltage (V) and the Y-axis represents current (A).

Referring to FIG. 3B, the threshold voltage Vt3 of “F-Read1” is about 6V, the threshold voltage Vt2 of “F-Read2” is about 4.5V, the memory window DA2 between “F-Read1” and “F-Read2” is shown as a double arrow. It can be seen that two threshold voltages can be read in the forward read operation, so the “0” and “1” states can be determined. Therefore, the memory layer 130 of the memory device 10 of the present invention is suitable as a memory element. Furthermore, when voltage is less than 4.5V, the currents of “R-Read1” and “R-Read2” are very small, and the memory device 10 is in a turn-off state. After 4.5V is applied to the memory device 10, the memory device 10 is in a turn-on state, so the memory layer 130 of the memory device 10 of the present invention is suitable as a switching element.

As can be seen from FIGS. 2A to 3B, the memory device 10 of the present application is suitable for the bipolar operation. Since the memory layer 130 of the memory device 10 of the present application can be used as a switching element and a memory element, the memory device 10 does not need to provide additional phase change memory materials, and the barrier layers disposed between the phase change memory material and the switching layer (such as OTS) can also be omitted.

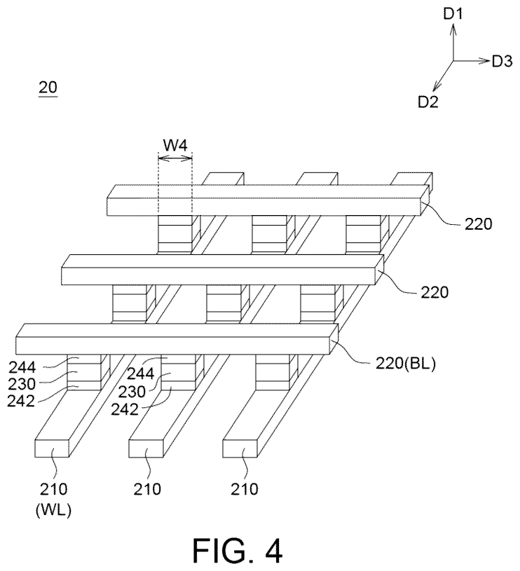

FIG. 4 is a three-dimensional view of a memory device 20 according to another embodiment of the present invention. The memory device 20 is, for example, a three-dimensional cross-point memory (3D cross-point memory, 3DXpoint). The elements in the memory device 20 which are the same or similar to the elements in the memory device 10 is designated as the same or similar reference numerals. The same or similar elements between the memory device 20 and the memory device 10 have the same or similar materials and functions. This will not be described in detail.

The memory device 20 includes a plurality of first electrodes 210, a plurality of second electrodes 220 and a plurality of memory layers 230. The first electrode 210, the memory layers 230 and the second electrodes 220 are stacked along a first direction D1. The extension direction of the first electrodes 210 is different from the extension direction of the second electrodes 220. Each of the first electrodes 210 extends along the second direction D2. Each of the second electrodes 220 extends along the third direction D3, and the first direction D1, the second direction D2, and the third direction D3 may be perpendicular to each other (the present invention is not limited thereto). That is, the extension direction of the first electrodes 210 is different from the extension direction of the second electrodes 220. The memory layers 230 are respectively formed at the intersections between the first electrodes 210 and the second electrodes 220. The first electrodes 210 can respectively serve as a word line WL, and the second electrodes 220 can respectively serve as a bit line BL.

In the present embodiment, the memory device 20 further includes a plurality of first barrier layers 242 and a plurality of second barrier layers 244. The first barrier layers 242 are disposed between the first electrodes 210 and the memory layers 230, and the second barrier layers 244 are disposed between the second electrodes 220 and the memory layers 230. The widths of the first barrier layers 242, the memory layers 230 and the second barrier layers 244 in the second direction D2 and the third direction D3 may be the same as each other, but the invention is not limited thereto. The first barrier layers 242 and the second barrier layers 244 can prevent metal ions in the first electrodes 210 and the second electrodes 220 from diffusing into the memory layers 230. According to some embodiments, the materials of the first barrier layers 242 and the second barrier layers 244 include carbon.

In other embodiments, the memory device 20 may not include the first barrier layers 242 and the second barrier layers 244, that is, the first electrodes 210 and the second electrodes 220 may be in direct contact with the memory layers 230.

According to some embodiments, a width W4 of the memory layer 230 in the third direction D3 is, for example, less than 20 nanometers (nm).

Similarly, the memory device 20 of the present invention is suitable for bipolar operation. Since the memory layer 230 of the memory device 20 in the present invention can be used as a switching element and a memory element, the memory device 20 does not need to include additional phase change memory materials.

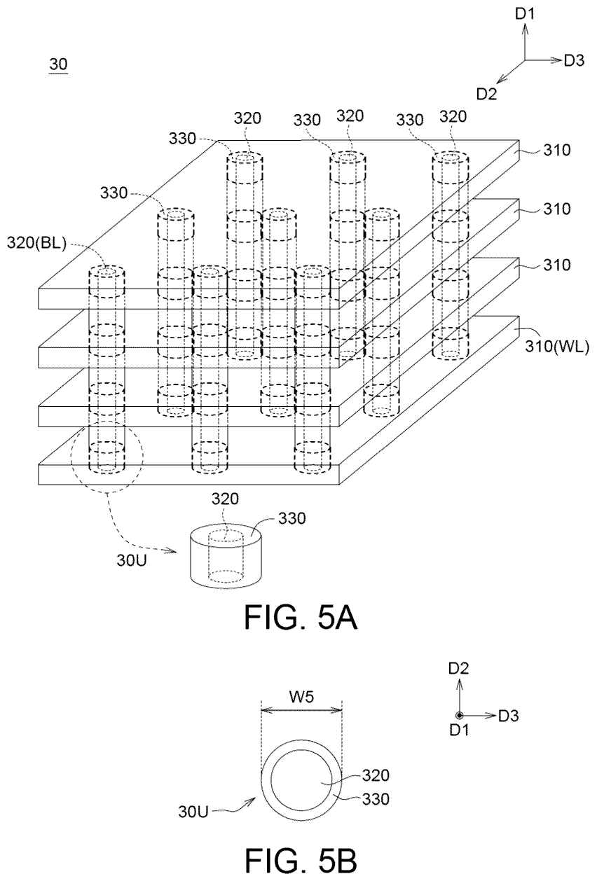

FIG. 5A shows a three-dimensional view of a memory device 30 according to a further embodiment of the present invention. FIG. 5B shows a top view of a memory cell 30U of the memory device 30 in FIG. 5A. The memory device 30 is, for example, a 3D vertical memory (3DVM). The elements in the memory device 30 which are the same or similar to the elements in the memory device 10 is designated as the same or similar reference numerals. The same or similar elements between the memory device 30 and the memory device 10 have the same or similar materials and functions. This will not be described in detail.

Referring to FIG. 5A, the memory device 30 includes a plurality of first electrodes 310, a plurality of second electrodes 320 and a plurality of memory layers 330. The first electrodes 310 are stacked along the first direction D1, and each of the first electrodes 310 is, for example, a layer extending along the second direction D2 and the third direction D3. In the present embodiment, the first electrodes 310 have four layers. However, the amount of first electrodes in the memory device of the present invention is not limited thereto. For example, the amount of first electrodes may be greater than four. The second electrodes 320 respectively pass through the first electrodes 310 along the first direction D1, and the memory layers 230 surround the second electrodes 320. Each of the second electrodes 320 is, for example, a columnar structure extending along the first direction D1. It should be understood that the amount of second electrodes of the memory device of the present invention is not limited to the amount of second electrodes 320 shown in FIG. 5A. In some embodiments, the amount of second electrodes of the memory device may be 1000×1000, 512×512, 256×256 or other suitable amount. Each of the memory layers 330 is, for example, a hollow columnar structure extending along the first direction D1. Each of intersections of the first electrodes 310, the second electrodes 320 and the memory layers 330 may correspond to a memory cell 30U.

Referring to FIG. 5B, in the top view of the memory cell 30U, the memory layer 330 may have a circular cross-section. According to some embodiments, a maximum width W5 of the memory layer 330 in the third direction D3 is, for example, greater than 100 nanometers (nm).

According to some embodiments, the first electrodes 310 can respectively serve as a word line WL, and the second electrodes 320 can respectively serve as a bit line BL. The desired memory cell 30U can be selected by applying voltages to the first electrodes 310 and the second electrodes 320.

Similarly, the memory device 30 of the present invention is suitable for bipolar operation. Since the memory layer 330 of the memory device 30 in the present application can be used as a switching element and a memory element, the memory device 30 does not need to include additional phase change memory materials.

According to some embodiments, after a stack of first electrodes 310 is formed, a plurality of holes may be formed passing through the stack of first electrodes 310 (e.g., by an etching process). Thereafter, the holes are filled with materials for forming the memory layers 330 and the second electrodes 320.

According to some embodiments, the memory device of the present invention may be called as a Selector-Only Memory (SOM).

According to some embodiments, the memory device of the present invention can be applied to a solid-state drive (SSD) or a dynamic random-access memory (DRAM).

As can be seen from the above contents, according to an embodiment of the present invention, a memory device is proposed. The memory device includes a first electrode, a second electrode and a memory layer disposed between the first electrode and the second electrode. The memory layer includes a composition including X wt % Cu, Y wt % Ge and Z wt % Se. X ranges between 3.33 and 26.66. Y ranges between 28.33 and 86.66. Z ranges between 10 and 45. Compared with a memory device that includes a phase change memory material, an ovonic threshold switch, and a barrier layer disposed between the phase change memory material and the ovonic threshold switch, since the memory layer in the memory device of the present invention includes a composition which can make the memory layer have the functions of both a switching element and a memory element, the memory device does not require additional phase change memory materials.

Therefore, it is beneficial to shrink the size of the semiconductor device, save manufacturing costs, and make the memory device have a lower leakage current, and the reliability can be increased and the performance of the memory device can be improved.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A memory device, comprising:
a first electrode;
a second electrode; and
a memory layer disposed between the first electrode and the second electrode, the memory layer comprising a composition, the composition comprising X wt % Cu, Y wt % Ge and Z wt % Se, wherein X ranges between 3.33 and 26.66, Y ranges between 28.33 and 86.66, and Z ranges between 10 and 45.

2. The memory device according to claim 1, wherein an atomic percentage (at %) ratio of Cu, Se and Ge in the composition of the memory layer is shown as follows:
Cu:Se:Ge=1:4:5.

3. The memory device according to claim 1, wherein the composition of the memory layer comprises GeSe, Ge and Cu₂GeSe₃.

4. The memory device according to claim 1, wherein the composition of the memory layer comprises 10 wt % GeSe, 10 wt % Ge and 80 wt % Cu₂GeSe₃.

5. The memory device according to claim 1, wherein the composition of the memory layer comprises 80 wt % GeSe, 10 wt % Ge and 10 wt % Cu₂GeSe₃.

6. The memory device according to claim 1, wherein the composition of the memory layer comprises 10 wt % GeSe, 80 wt % Ge and 10 wt % Cu₂GeSe₃.

7. The memory device according to claim 1, wherein the memory layer contacts the first electrode and the second electrode.

8. The memory device according to claim 1, wherein an amount of the first electrode, an amount of the second electrode and an amount of the memory layer are a plural, and an extension direction of the first electrodes are different from an extension direction of the second electrodes, and the memory layers are formed at intersections of the first electrodes and the second electrodes.

9. The memory device according to claim 8, wherein the first electrodes respectively serve as a word line, and the second electrodes respectively serve as a bit line.

10. The memory device according to claim 8, further comprising a plurality of first barrier layers and a plurality of second barrier layers, the first barrier layers disposed on the first electrodes and the memory layers, the second barrier layers disposed between the second electrodes and the memory layers.

11. The memory device according to claim 10, wherein a material of the first barrier layers and the second barrier layers includes carbon.

12. The memory device according to claim 8, wherein the first electrodes are stacked along a first direction, and the second electrodes respectively pass through the first electrodes along the first direction, and the memory layers surround the second electrodes.

13. The memory device according to claim 1, wherein the memory layer does not include a phase change memory material.

14. The memory device according to claim 1, wherein the memory layer serves as a switching element and a memory element.
